(19) United States
(12) Patent Application Publication
(10) Pub. No.: US 2003/0215570 A1
(43) Pub. Date: Nov. 20, 2003

(54) Deposition of silicon nitride

(75) Inventors: Sean M. Seutter, San Jose, CA (US); Errol Antonio C. Sanchez, Dublin, CA (US); Yazin Wang, Fremont, CA (US)

Correspondence Address: Patent Counsel, APPLIED MATERIALS, INC., P.O. Box 450A, Santa Clara, CA, 95052, US

(73) Assignee: APPLIED MATERIALS, INC.

(21) Appl. No.: 10/263,555

(22) Filed: Oct. 2, 2002

Related U.S. Application Data
(60) Provisional application No. 60/380,943, filed on May 16, 2002.

(51) Int. Cl. C23C 16/00

(52) U.S. Cl. 427/255.394

(57) ABSTRACT

Embodiments of the present invention relate to methods and apparatus for depositing a silicon nitride film. More particularly, embodiments of the present invention relate to methods and apparatus for depositing a silicon nitride film by cyclical layer deposition. One method for depositing a silicon nitride film generally comprises separately introducing one or more pulses of a nitrogen precursor and one or more pulses of a silicon precursor to a region adjacent to the substrate surface. A portion of the pulses of the nitrogen precursor and a portion of the pulses of the silicon precursor are present together at the region adjacent the substrate surface. Another embodiment for depositing a silicon nitride film comprises dosing a continuous flow of a purge gas with at least one pulse of a silicon precursor and at least one pulse of a nitrogen precursor. Each pulse of the silicon precursor and the nitrogen precursor is provided for a time period between about 0.01 seconds and about 2.0 seconds. A time period between the pulses of nitrogen precursor and the pulses of silicon precursor is between about 0.01 seconds and about 2.0 seconds. Still another embodiment for depositing a silicon nitride film comprises providing pulses of the silicon precursor and the nitrogen precursor to a substrate at a substrate temperature of about 600° C.

### CROSS-REFERENCE TO RELATED APPLICATIONS

This application claims benefit of U.S. Provisional Patent Application Serial No. 60/380,943, filed May 16, 2002, which is herein incorporated by reference.

### BACKGROUND OF THE INVENTION

1. Field of the Invention

Embodiments of the present invention relate to methods and apparatus for depositing a silicon nitride film. More particularly, embodiments of the present invention relate to method and apparatus for depositing a silicon nitride film by cyclical layer deposition.

2. Description of the Related Art

Reliably producing sub-micron and smaller features is one of the key technologies for the next generation of very large scale integration (VLSI) and ultra large scale integration (ULSI) of semiconductor devices. However, as the fringes of circuit technology are pressed, the shrinking dimensions of features in VLSI and ULSI technology have placed additional demands on the processing capabilities.

Silicon nitride films are used as insulating films, passivating or protective films, and in other applications in the formation of integrated circuits. Problems with prior techniques for depositing silicon nitride films include poor conformal deposition over stepped topography, high amounts of impurities incorporated into the film, high thermal budget, and/or low through-put.

Atomic layer deposition is one technique being explored for depositing silicon nitride. One example of one cycle of an atomic layer deposition sequence includes providing a pulse of a silicon precursor to a chamber for self-limiting adsorption of a monolayer of the silicon precursor over a substrate, providing a pulse of a purge gas and/or a pump evacuation to completely remove the silicon precursor from the chamber, providing a pulse of a nitrogen precursor for self-limiting adsorption of a monolayer of the nitrogen precursor over the substrate, and providing a pulse of a purge gas and/or a pump evacuation to completely remove the nitrogen precursor from the chamber. Each cycle forms a monolayer of a silicon nitride film due to the alternating adsorption of monolayers of the silicon precursor and nitrogen precursor over the substrate. The pulses of the purge gas and/or the pump evacuation between the pulses of the silicon precursor and the nitrogen precursor prevent gas phase reactions of the precursors and prevent deposition of more than a monolayer of silicon nitride during each cycle. The cycle may be repeated to a desired thickness of the silicon nitride film. One problem with atomic layer deposition of silicon nitride films is the long exposure time of the pulses of the precursors required to saturate the substrate. Another problem with atomic layer deposition of silicon nitride films is the long time period required for the pulses of the purge gas and/or the pump evacuation between pulses of the precursors to completely remove precursors from the chamber. Thus, the deposition rate and through-put of atomic layer deposition of silicon nitride is low.

Therefore, there is a need for an improved method and apparatus of depositing silicon nitride films.

### SUMMARY OF THE INVENTION

Embodiments of the present invention relate to methods and apparatus for depositing a silicon nitride film. More particularly, embodiments of the present invention relate to methods and apparatus for depositing a silicon nitride film by cyclical layer deposition. One method for depositing a silicon nitride film generally comprises separately introducing one or more pulses of a nitrogen precursor and one or more pulses of a silicon precursor to a region adjacent to the substrate surface. A portion of the pulses of the nitrogen precursor and a portion of the pulses of the silicon precursor are present together at the region adjacent the substrate surface. Another embodiment for depositing a silicon nitride film comprises dosing a continuous flow of a purge gas with at least one pulse of a silicon precursor and at least one pulse of a nitrogen precursor. Each pulse of the silicon precursor and the nitrogen precursor is provided for a time period between about 0.01 seconds and about 2.0 seconds. A time period between the pulses of nitrogen precursor and the pulses of silicon precursor is between about 0.01 seconds and about 2.0 seconds. Still another embodiment for depositing a silicon nitride film comprises providing pulses of the silicon precursor and the nitrogen precursor to a substrate at a substrate temperature of about 600° C.

### BRIEF DESCRIPTION OF THE DRAWINGS

So that the manner in which the above recited features of the present invention, as well as other features set forth herein, are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a flow chart illustrating one embodiment of a method of depositing a silicon nitride film by cyclical layer deposition.

FIG. 2A is a graph of one embodiment depicting the control signals for cyclical layer deposition of a silicon nitride film.

FIG. 2B is a graph of one embodiment depicting the amount of the nitrogen precursor and the silicon precursor remaining at a region adjacent a substrate surface over time according to the control signals of FIG. 2A.

FIG. 3A is a graph of another embodiment depicting the control signals for cyclical layer deposition of a silicon nitride film.

FIG. 3B is a graph of one embodiment depicting the amount of the silicon precursor and the nitrogen precursor remaining at a region adjacent a substrate surface over time according to the control signals of FIG. 3A.

FIG. 4A is a graph of another embodiment depicting the control signals for cyclical layer deposition of a silicon nitride film.

FIG. 4B is a graph of one embodiment depicting the amount of the nitrogen precursor and the silicon precursor remaining at a region adjacent a substrate surface over time according to the control signals of FIG. 4A.

FIG. 5 is a schematic cross-sectional view of one embodiment of an application of a silicon nitride film utilized in one stage in the formation of a transistor structure.

### DETAILED DESCRIPTION OF THE PREFERRED EMBODIMENT

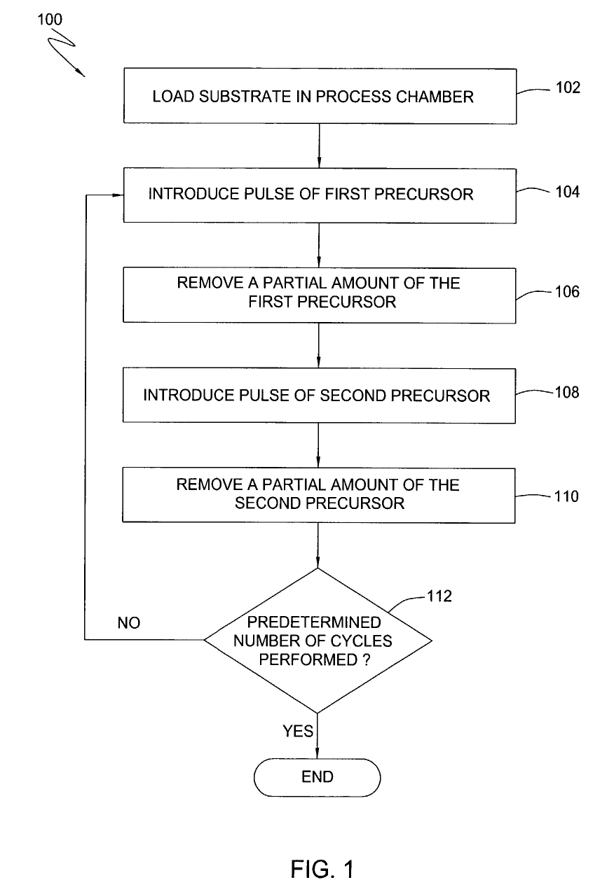

FIG. 1 is a flow chart illustrating one embodiment of method 100 of depositing a silicon nitride film by cyclical layer deposition. The term “cyclical layer deposition” as used herein refers to the sequential introduction of one or more compounds to deposit a thin layer of material over a substrate and includes processing techniques such as atomic layer deposition, rapid pulsed chemical vapor deposition, and fast atomic layer deposition. Compounds can be reactants, reductants, precursors, catalysts, plasma species, and mixtures thereof. Sequentially providing compounds may result in the formation of thin layers of material over a substrate. The term “substrate” as used herein is intended to include any workpiece upon which film processing is performed and may be used to denote a substrate, such as a semiconductor substrate or a glass substrate, as well as other material layers formed on the substrate, such as a dielectric layer, conductive layer, etc. Each thin layer of material may be less than a monolayer, a monolayer, or more than a monolayer of material. The sequential introduction of compounds may be repeated to deposit a plurality of thin layers forming a conformal film to a desired thickness.

The following steps of the method 100 may be performed in a suitable chamber. As shown in step 102, a substrate is provided to the process chamber. The process chamber conditions, such as for example the substrate temperature and pressure, may be adjusted. In step 104, a pulse of a first precursor is introduced to a region adjacent a substrate surface. In step 106, a partial amount of the first precursor is removed from the region adjacent the substrate surface prior to step 108. In step 108, a pulse of a second precursor is introduced to the region adjacent the substrate surface. In optional step 110, a partial amount of the second precursor is removed from the region adjacent the substrate surface. Steps 104, 106, 108, 110 are repeated until a predetermined number of cycles are performed to form a silicon nitride film to a desired thickness.

In one embodiment of the method 100, a continuous flow of a purge gas is provided to the chamber. The pulses of the first precursor and the pulses of the second precursor are dosed into the continuous flow of the purge gas. Removal of a partial amount of the first precursor and/or a partial amount of the second precursor comprises providing the continuous flow of the purge gas for a time period sufficient to partially purge the region adjacent the substrate surface of the selected precursor(s). In another embodiment of the method 100, pulses of a purge gas are provided to the chamber between the pulses of the first precursor and the pulses of the second precursor. Removal of a partial amount of the first precursor and/or a partial amount of the second precursor comprises providing pulses of the purge gas for a time period sufficient to partially purge the region adjacent the substrate surface of the selected precursor(s). The terms “partially purge,” “removal of a partial amount,” “removing a partial amount” as used herein refer to partially removing one or more selected precursors so that more than trace amounts of the non-adsorbed selected precursor(s) remain at the region adjacent the substrate surface. The term “region adjacent the substrate surface” as used herein refers to that when precursor(s) are present at the region adjacent the substrate surface, the precursors may participate in gas phase processes and/or surface phase processes depending on the processing conditions.

The precursors utilized in cyclical layer deposition of a silicon nitride film are a nitrogen precursor and a silicon precursor (i.e., the first precursor is a nitrogen precursor and the second precursor is a silicon precursor or the first precursor is a silicon precursor and the second precursor is a nitrogen precursor). The silicon precursor preferably comprises dichlorosilane (SiH₂Cl₂) or hexachlorodisilane (Si₂Cl₆), and most preferably comprises hexachlorodisilane (Si₂Cl₆). Other silicon precursors may include, but are not limited to silicon tetrachloride (SiCl₄), silane (SiH₄), disilane (Si₂H₆), chlorosilane (SiH₃Cl), dichlorosilane (SiH₂Cl₂), trichlorosilane (SiHCl₃), other silicon-containing compounds, and derivatives thereof. However, preferably, a carbon-free silicon containing compound is used. The nitrogen precursor preferably comprises ammonia (NH₃). Examples of other nitrogen precursors may include, but are not limited to hydrazine (N₂H₄), other NₓH_{y} compounds with x and y being integers, dimethyl hydrazine ((CH₃)₂N₂H₂), t-butylhydrazine (C₄H₉N₂H₃), phenylhydrazine (C₆H₅N₂H₃), 2,2′-azoisobutane ((CH₃)₆C₂N₂), ethylazide (C₂H₅N₃), other nitrogen-containing compounds, and derivatives thereof. However, preferably, a carbon-free nitrogen precursor is used. The purge gas preferably comprises nitrogen gas (N₂). Examples of other purge gases may include argon gas (Ar), helium gas (He), other suitable gases, and mixtures thereof. The use of hydrogen gas (H₂) as a purge gas is less preferred due to the potential of incorporation of the hydrogen gas in the formed silicon nitride film.

Preferably, the silicon precursor used is hexachlorodisilane having a low content of impurities. It has been observed that hexachlorodisilane having a high content of aluminum, copper, and/or germanium impurities may adversely affect the quality of the deposited silicon nitride film. Preferably, hexachlorodisilane has a low content of aluminum impurities of about 3,700 ppb (parts per billion) or less, more preferably about 3.0 ppb or less, copper impurities of about 6,800 ppb or less, preferably about 10 ppb or less, germanium impurities of about 1,200 ppb or less, preferably about 17 ppb or less, and titanium impurities of about 10 ppb or less.

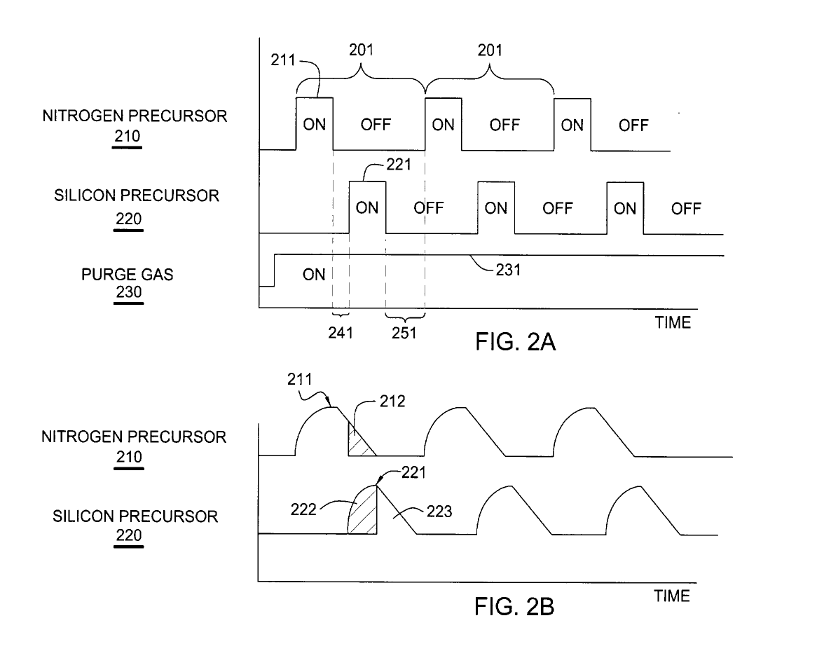

FIG. 2A is a graph of one embodiment depicting the control signals for cyclical layer deposition of a silicon nitride film according to the method described in

FIG. 1. One cycle 201 comprises providing a continuous flow 231 of a purge gas 230 to a chamber. During the continuous flow 231 of the purge gas 230, a pulse 211 of a nitrogen precursor 210 is introduced into the chamber and dosed into the stream of the continuous flow 231 of the purge gas 230. After the pulse 211 of the nitrogen precursor 210 is introduced, the flow 231 of the purge gas 230 continues into the chamber without any precursor introduced into the chamber for a first time period 241. The first time period 241 is for a short duration in which the purge gas only partially purges a region adjacent the substrate surface of the nitrogen precursor. Then, during the continuous flow 231 of the purge gas 230, a pulse 221 of a silicon precursor 220 is introduced into the chamber and dosed into the stream of the continuous flow 231 of the purge gas 230. Since the region adjacent the substrate surface was only partially purged of the nitrogen precursor prior to introduction of the pulse 221 of the silicon precursor 220, amounts of the nitrogen precursor and amounts of the silicon precursor are present together at the region adjacent the substrate surface. After the pulse 221 of the silicon precursor 220 is introduced, the flow 231 of the purge gas 230 continues into the chamber without any precursors introduced into the chamber for a second time period 251. Preferably, the second time period 251 is for a duration sufficient to substantially purge the region adjacent the substrate surface of the silicon precursor. The cycle 201 may be repeated to deposit a desired thickness of the silicon nitride film. As shown in FIG. 2A, the cycle 201 starts with a pulse of a nitrogen precursor. Alternatively, the cycle may start with a pulse of a silicon precursor. The term “present together at the region adjacent the substrate surface” as used herein refers to amounts of non-adsorbed precursors being present simultaneously at the region adjacent the substrate surface. The term “substantially purge the region adjacent the substrate surface” as used herein refers to substantially removing one or more selected precursors so than only trace amounts of non-adsorbed selected precursor(s) remain at the region adjacent the substrate surface.

Not wishing to be bound by theory unless explicitly set forth in the claims, FIG. 2B is a graph of one embodiment depicting the amount of the nitrogen precursor and the silicon precursor remaining in at a region adjacent the substrate surface over time after a partial purge of nitrogen precursor from the region adjacent the substrate surface between the pulses of the nitrogen precursor and the pulses of the silicon precursor according to the control signals of FIG. 2A. A portion 212 of the nitrogen precursor 210 from the pulse 211 remains at the region adjacent the substrate surface during introduction of the silicon precursor 220 and overlaps with a portion 222 of the silicon precursor from the pulse 221. The portion 212 of the nitrogen precursor may be smaller than the portion 222 of the silicon precursor due to the partial purge of the nitrogen precursor 210 as a result of the flow of the purge gas 230 provided from a time period 241 (FIG. 2A) between the pulse 211 of the nitrogen precursor and the pulse 221 of the silicon precursor.

In reference to FIG. 2B, in one theory, it is believed silicon nitride is deposited at least partially in a chemical vapor deposition mechanism (co-reaction mode) since a portion 212 of the nitrogen precursor and a portion 222 of the silicon precursor are present together at the region adjacent the substrate surface. Since the time period 241 (FIG. 2A) of the flow of the purge gas between the pulse 211 of the nitrogen precursor and the pulse 221 of the silicon precursor is less than the time period required to completely purge the nitrogen precursor from the region adjacent the substrate surface, the duration between these pulses is short and the cycle time is less in comparison to atomic layer deposition processes. In addition, since silicon nitride is at least partially deposited in a chemical vapor deposition mechanism, it is believed that more than a monolayer of silicon nitride is deposited per cycle (i.e., co-reaction has a higher deposition rate). Therefore, the deposition rate per cycle and through-put are also increased in comparison to atomic layer deposition processes. It is believed that since the portion 222 of the silicon precursor is larger than the overlapping portion 212 of the nitrogen precursor, chemical vapor deposition of silicon nitride occurs in a silicon rich environment which may help provide enhanced film qualities and may help provide conformal deposition.

In another theory, it is believed silicon nitride is deposited at least partially in an adsorption process since a portion 223 of the silicon precursor from the pulse 221 of the silicon precursor 220 is present at the region adjacent the substrate surface without substantial amounts of the nitrogen precursor 210 remaining at the region adjacent the substrate surface. It is believed deposition in an adsorption mechanism helps provide conformal deposition and helps provide a silicon nitride film with less impurities. It is believed that the portion 223 of the pulse 220 of the silicon precursor may act as an anneal, getter, or other film quality improvement step. Deposition of silicon nitride may operate in one of the described theories, a combination of the described theories, or in other mechanisms.

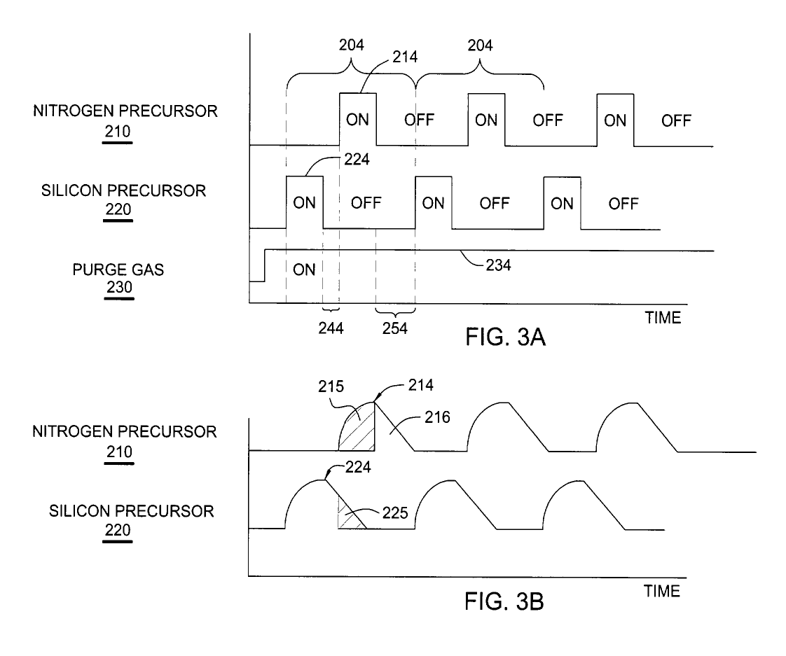

FIG. 3A is a graph of another embodiment depicting the control signals for cyclical layer deposition of a silicon nitride film according to the method described in FIG. 1. One cycle 204 comprises providing a continuous flow 234 of a purge gas 230 to a region adjacent the substrate surface. During the continuous flow 234 of the purge gas 230, a pulse 224 of a silicon precursor 220 is introduced to the region adjacent the substrate surface and dosed into the stream of the continuous flow 234 of the purge gas 230. After the pulse 224 of the silicon precursor 220 is introduced, the flow 234 of the purge gas 230 continues to the region adjacent the substrate surface without any precursor introduced to the region adjacent the substrate surface for a first time period 244. The first time period 244 is for a short duration in which the purge gas. only partially purges the region adjacent the substrate surface of the silicon precursor. Then, during the continuous flow 234 of the purge gas 230, a pulse 214 of a nitrogen precursor 210 is introduced to the region adjacent the substrate surface and dosed into the stream of the continuous flow 234 of the purge gas 230. Since the region adjacent the substrate surface was only partially purged of the silicon precursor prior to introduction of the pulse 214 of the nitrogen precursor 210, amounts of the silicon precursor and amounts of the nitrogen precursor are present together at the region adjacent the substrate surface. After the pulse 214 of the nitrogen precursor 210 is introduced, the flow 234 of the purge gas 230 continues to the region adjacent the substrate surface without any precursors introduced to the region adjacent the substrate surface for a second time period 254. Preferably, the second time period 254 is for a duration sufficient to substantially purge the region adjacent the substrate surface of the nitrogen precursor. The cycle 204 may be repeated to deposit a desired thickness of the silicon nitride film. As shown in FIG. 3A, the cycle 204 starts with a pulse of a silicon precursor. Alternatively, the cycle may start with a pulse of a nitrogen precursor.

Not wishing to be bound by theory unless explicitly set forth in the claims, FIG. 3B is a graph of one embodiment of the amount of the silicon precursor and the nitrogen precursor remaining in at a region adjacent the substrate surface over time after a partial purge of silicon precursor from the region adjacent the substrate surface between the pulses of the silicon precursor and the pulses of the nitrogen precursor according to the control signals of FIG. 3A. A portion 225 of the silicon precursor 220 from the pulse 224 remains at the region adjacent the substrate surface during introduction of the silicon precursor 220 and overlaps with a portion 215 of the nitrogen precursor 210 from the pulse 214. The portion 225 of the silicon precursor may be smaller than the portion 215 of the nitrogen precursor due to the partial purge of the silicon precursor 220 as a result of the flow of the purge gas 230 provided from a time period 244 (FIG. 3A) between the pulse 224 of the silicon precursor and the pulse 214 of the nitrogen precursor.

In reference to FIG. 3B, in one theory, it is believed silicon nitride is deposited at least partially in a chemical vapor deposition mechanism since a portion 225 of the silicon precursor and a portion 215 of the nitrogen precursor are present together at the region adjacent the substrate surface. Since the time period 244 (FIG. 3A) of the flow of the purge gas between the pulse 224 of the silicon precursor and the pulse 214 of the nitrogen precursor is less than the time period required to completely purge the silicon precursor from the region adjacent the substrate surface, the duration between these pulses is short and the cycle time is less in comparison to atomic layer deposition processes. In addition, since silicon nitride is at least partially deposited in a chemical vapor deposition mechanism, it is believed that more than a monolayer of silicon nitride is deposited per cycle. Therefore, the deposition rate per cycle and through-put are also increased in comparison to atomic layer deposition processes. It is believed that since the portion 215 of the nitrogen precursor is larger than the overlapping portion 225 of the silicon precursor, chemical vapor deposition of silicon nitride occurs in a nitrogen rich environment which may help provide enhanced film qualities and may help reduce impurities (such as chlorine) incorporated into the film.

In another theory, it is believed silicon nitride is deposited at least partially in an adsorption process since a portion 216 of the nitrogen precursor from the pulse 214 of the nitrogen precursor 210 is present at the region adjacent the substrate surface without substantial amounts of the silicon precursor 220 remaining at the region adjacent the substrate surface. It is believed deposition in an adsorption mechanism helps provides good conformal deposition and provides a silicon nitride film with less impurities. It is believed that the portion 216 of the pulse 210 of the nitrogen precursor may act as an anneal, getter, or other film quality improvement step. Deposition of silicon nitride may operate in one of the described theories, a combination of the described theories, or in other mechanisms

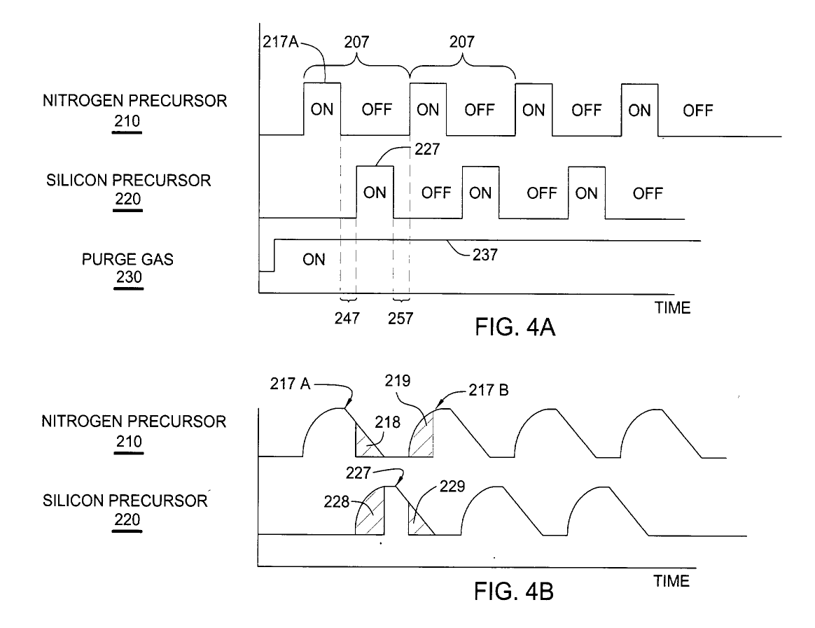

FIG. 4A is a graph of another embodiment depicting the control signals for cyclical layer deposition of a silicon nitride film according to the method described in FIG. 1. One cycle 207 comprises providing a continuous flow 237 of a purge gas 230 to a region adjacent the substrate surface. During the continuous flow 237 of the purge gas 230, a pulse 217A of a nitrogen precursor 210 is introduced to the region adjacent the substrate surface and dosed into the stream of the continuous flow 237 of the purge gas 230. After the pulse 217A of the nitrogen precursor 210 is introduced, the flow 237 of the purge gas 230 continues to the region adjacent the substrate surface without any precursor introduced to the region adjacent the substrate surface for a first time period 247. The first time period 247 is for a short duration in which the purge gas only partially purges the region adjacent the substrate surface of the nitrogen precursor. Then, during the continuous flow 237 of the purge gas 230, a pulse 227 of a silicon precursor 220 is introduced to the region adjacent the substrate surface and dosed into the stream of the continuous flow 237 of the purge gas 230. Since the region adjacent the substrate surface was only partially purged of the nitrogen precursor prior to introduction of the pulse 227 of the silicon precursor 220, amounts of the nitrogen precursor and amounts of the silicon precursor are present together at the region adjacent the substrate surface. After the pulse 227 of the silicon precursor 220 is introduced, the flow 237 of the purge gas 230 continues to the region adjacent the substrate surface without any precursors introduced to the region adjacent the substrate surface for a second time period 257. The second time period 257 is for a short duration in which the purge gas only partially purges the region adjacent the substrate surface of the silicon precursor. In a subsequent cycle, since the region adjacent the substrate surface was only partially purged of the silicon precursor prior to introduction of the pulse 217B of the nitrogen precursor 210, amounts of the nitrogen precursor and amounts of the silicon precursor are present together at the region adjacent the substrate surface. The cycle 207 may be repeated to deposit a desired thickness of the silicon nitride film. As shown in FIG. 4A, the cycle 207 starts with a pulse of a nitrogen precursor. Alternatively, the cycle may start with a pulse of a silicon precursor.

Not wishing to be bound by theory unless explicitly set forth in the claims, FIG. 4B is a graph of one embodiment depicting the amount of the nitrogen precursor and the silicon precursor remaining at a region adjacent the substrate surface over time after a partial purge of nitrogen precursor and after a partial purge of the silicon precursor from the region adjacent the substrate surface between the. pulses of precursors according to the control signals of FIG. 4A. A portion 218 of the nitrogen precursor 210 from the pulse 217A remains at the region adjacent the substrate surface during introduction of the silicon precursor 220 and overlaps with a portion 228 of the silicon precursor 220 from the pulse 227. The portion 218 of the nitrogen precursor may be smaller than the portion 228 of the silicon precursor due to the partial purge of the nitrogen precursor 210 as a result of the flow of the purge gas 230 provided from a time period 247 (FIG. 4A) between the pulse 217A of the nitrogen precursor and the pulse 227 of the silicon precursor. Similarly, a portion 229 of the silicon precursor 220 from the pulse 227 remains at the region adjacent the substrate surface during introduction of the nitrogen precursor 210 and overlaps with a portion 219 of the nitrogen precursor 210 from the pulse 217B. The portion 229 of the silicon precursor may be smaller than the portion 219 of the nitrogen precursor due to the partial purge of the silicon precursor 220 as a result of the flow of the purge gas 230 provided from a time period 257 (FIG. 4A) between the pulse 217B of the nitrogen precursor and the pulse 227 of the silicon precursor.

In reference to FIG. 4B, in one theory, it is believed silicon nitride is deposited at least partially in a chemical vapor deposition mechanism since portions 218, 219 of the nitrogen precursor and portions 228, 229 of the silicon precursor are present together at the region adjacent the substrate surface. Since the time periods 247, 257 (FIG. 4A) of the flow of the purge gas between the pulses 217 of the nitrogen precursor and the pulses 227 of the silicon precursor is less than the time period required to completely purge the nitrogen precursor and the silicon precursor from the region adjacent the substrate surface, the duration between these pulses is short and the cycle time is less in comparison to atomic layer deposition processes. In addition, since silicon nitride is at least partially deposited in a chemical vapor deposition mechanism, it is believed that more than a monolayer of silicon nitride is deposited per cycle. Therefore, the deposition rate per cycle and through-put are also increased in comparison to atomic layer deposition processes. It is also believed that since the portion 228 of the silicon precursor is larger than the overlapping portion 218 of the nitrogen precursor and since the portion 219 of the nitrogen precursor is larger than the overlapping portion 229 of the silicon precursor, alternating thin layers of silicon nitride are formed in a silicon-rich environment and are formed in a nitrogen-rich environment which may help provide enhanced film qualities.

In another theory, it is believed silicon nitride may be deposited at least partially in an adsorption process. It is believed deposition in an adsorption mechanism helps provides good conformal deposition and provides a silicon nitride film with less impurities. Deposition of silicon nitride may operate in one of the described theories, a combination of the described theories, or in other mechanisms

One exemplary process of cyclical layer deposition of a silicon nitride film by providing pulses of a silicon precursor, preferably hexachlorodisilane (Si₂Cl₆) and pulses of a nitrogen precursor, preferably ammonia (NH₃), includes the following process conditions which may be performed in the chamber as described below in reference to FIG. 6 or may be performed in other suitable chambers. The substrate temperature may be maintained at about 800° C. or less, preferably about 600° C. or less, at a chamber pressure of 50 Torr or less, preferably between about 8 Torr and about 10 Torr. The silicon precursor, such as Si₂Cl₆, is delivered through a first valve, preferably a three-way valve, at a flow rate between about 100 mgm (milligrams per minute) and about 1000 mgm, preferably at a flow rate of about 500 mgm in pulses between about 0.01 seconds and about 2.0 seconds, preferably about 0.2 second or less. A carrier gas, such as nitrogen gas (N₂), argon gas (Ar), helium gas (He), other suitable gases, and mixtures thereof, may be delivered with the silicon precursor. The use of hydrogen gas (H₂) as a carrier gas is less preferred due to the potential of incorporation of the hydrogen gas in the formed silicon nitride film. Preferably, a nitrogen carrier gas (N₂) is delivered with the silicon precursor and delivered at a flow rate between about 0.5 slm (liters per minute) and about 5.0 slm, preferably at a flow rate of about 1.5 slm. The nitrogen precursor, such as NH₃, is delivered through a second valve, preferably a three-way valve, at a flow rate between about 0.5 slm (liters per minute) and about 5.0 slm, preferably at a flow rate of about 2.0 slm in pulses between about 0.01 seconds and about 2.0 seconds, preferably about 0.4 second or less. A carrier gas, such as helium gas (He), argon gas (Ar), hydrogen gas (H₂), nitrogen gas (N₂), other suitable gases, and mixtures thereof, may be delivered with the ammonia. Preferably, the nitrogen precursor is delivered without the aid of a carrier gas. The nitrogen precursor, such as NH₃, may or may not be pre-heated. It is believed that pre-heating the nitrogen precursor may increase its reactivity.

Preferably, a continuous flow of a purge gas, preferably a nitrogen purge gas, is provided through both the first valve and the second valve and is delivered at a flow rate between about 0.5 slm and about 5.0 slm, preferably about 1.0 slm, for each valve. The time period between the pulses of the silicon precursor and the pulses of the nitrogen precursor is about 0.01 seconds and about 2.0 seconds, preferably about 0.2 second or less. It is believed that a time period of about 0.2 seconds or less between the pulses of the precursors provides a partial purge of a region adjacent the substrate surface resulting in at least some co-reaction. The shorter the purge, the more likely co-reaction occurs. The cycle time is about 5.0 seconds or preferably less, preferably about 1.0 second or less. For a substrate temperature of 800° C. or less, the above process regime utilizing the precursors of Si₂Cl₆ and NH₃ provides a deposition rate of about 500Å per minute or less. For a substrate temperature of 600° C. or less, the above process regime utilizing the precursors of Si₂Cl₆ and NH₃ provides a deposition rate between about 30Å per minute and about 100Å per minute. In one aspect, cyclical layer deposition of silicon nitride at a temperature of about 600° C. or less provides a low temperature process (e.g., a low thermal budget process) for the formation of silicon nitride over devices which may be damaged or deactivated by high temperature.

In one embodiment, the chamber lid, body, and/or central manifold are heated to a temperature between about 60° C. and about 150° C., preferably about 70° C., by a temperature control fluid provided through fluid channels disposed therein, by resistive heating elements, and/or by other heating devices. The valves and/or the faceplate may also be heated to a temperature between about 60° C. to about 150° C., preferably about 70° C. For example, the valves and the faceplate may be heated through heat conduction with the chamber lid and central manifold. In one aspect, it is believed that heating chamber-components reduces the formation of reaction by-products such as ammonium chloride (NH₄Cl) particles and adducts. In another aspect, heating the valves may reduce condensation of precursor onto valve components, such as the diaphragm.

An in-situ chamber clean may also be performed to maintain process uniformity and to prevent particle contamination (i.e. from SiN formed on inner chamber surfaces). The in-situ clean may include a remote plasma of NF₃ provided into the chamber at a heater temperature of 400° C. The plasma clean can be performed at any time, for example, after every substrate, after every couple of substrates, after every 100 substrates, after every 200 substrates, etc.

The flow rates of the precursors and/or carrier gases are described in reference to a mass flow controller. Although the precursor and/or carrier gas is delivered in pulses, the flow rates represent the total amount of the precursor and/or carrier gas delivered over time. The above described process regime may also include delivery of other purge gases. For example, a bottom purge gas, such as a nitrogen purge gas, may be provided at a flow rate of between about 0.5 slm and about 5.0 slm, preferably about 2.0 slm. A liner purge gas, such as a nitrogen purge gas, may be provided at a flow rate of between about 0.5 slm and about 5.0 slm, preferably about 3.0 slm. A slit purge gas, such as a nitrogen purge gas, may be provided at a flow rate of between about 0.5 slm and about 5.0 slm, preferably about 1.0 slm.

It has been observed that the cyclical layer deposition of silicon nitride by the method described herein provides a high quality silicon nitride film. Step coverage of about 95% or greater, and 97% or greater, and a pattern loading effect of about 5% or less, and about 1% or less, for the deposition of silicon nitride over features having an aspect ratio of about 4:1 or greater have been observed. Pattern loading effect is defined as the percentage film thickness difference between a flat isolated area and a dense structured area. In addition, the deposited silicon nitride films have a purity level of 95.0% or greater and have a low hydrogen and chlorine impurity content.

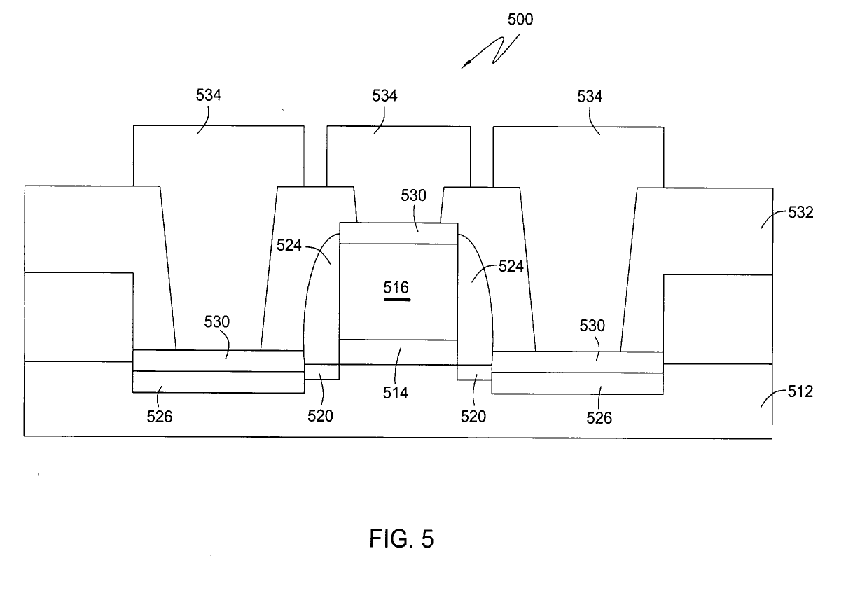

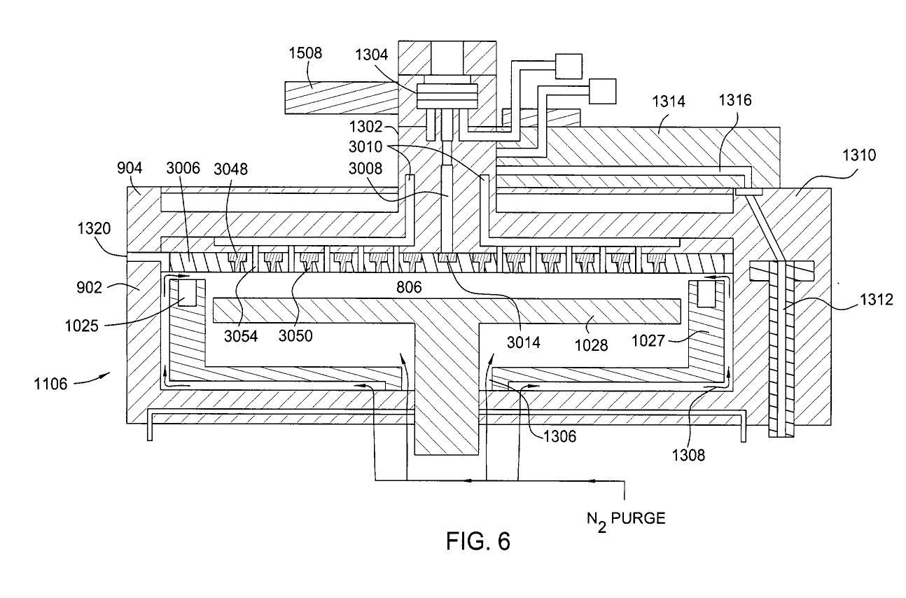

Cyclical layer deposition of silicon nitride by the methods described herein is useful in the formation of spacers in transistors application and is especially useful in the formation of spacers in sub-100 nm transistor devices due to the good patterned loading effect, low thermal budget, and high through-put of the deposition process. FIG. 5 is a schematic cross-sectional view of one embodiment of specific applications of a silicon nitride film utilized in one stage in the formation of a transistor structure. Other applications for a silicon nitride film are possible. The transistor structure 500 comprises a substrate 512, such as a semiconductor substrate. A gate dielectric layer 514 is formed over the substrate 512. The gate dielectric layer 514 may comprise a silicon nitride layer, a stack including one or more silicon nitride layer (such as a SiN/SiO₂ stack or a SiN/SiO₂/SiN stack), or other dielectric materials. In one embodiment, the dielectric layer 514 is deposited to a thickness of less than about 30 Å, preferably between about 5 Å and about 30Å. A gate electrode 516, such as a polysilicon layer or other conductive materials, is formed over the gate dielectric layer 514. A doping process is performed to form a lightly doped region 520. Sidewall spacers 524 comprising silicon nitride or other dielectric materials are formed flanking the gate 514, 516. In one embodiment, the sidewall spacers 524 are formed by depositing silicon nitride to a thickness between about 200 Å and about 400 Å. A doping process is performed to more heavily dope source/drain regions 526. A reactive metal, such as cobalt or titanium, is deposited over the source/drain regions 526 and over the gate 514, 516 to form metal silicide contacts 530. A passivation layer 532 and metal contacts 534 are formed 534 over the metal silicide contacts.

FIG. 6 is a schematic cross-sectional view of one embodiment of a processing chamber 1106 which may be useful in performing the processes as disclosed herein. Of course, other processing chambers and systems may also be used. The processing chamber includes a chamber body 902 and a chamber lid 904. The chamber body 902 defines a cavity. A substrate support 1028 is disposed within the cavity of the chamber body 902 and includes a substrate receiving surface for supporting a substrate thereon. Atop the lid 904 is a central manifold 1302 for distributing gases through a dual-channel faceplate 3006 to a processing region 806 between the faceplate 3006 and the substrate support 1028.

The chamber body 902 includes a plurality of discrete wall conduits 1312 for delivery of gases therethrough. At least one of the wall conduits 1312a is coupled to a silicon precursor source. At least one of the wall conduits 1312b is coupled to a nitrogen precursor source. At least one of the wall conduits 1312c is coupled to a purge gas source(s). A plurality of lid conduits 1310 couples each of the wall conduits 1312a-c to a plurality of central manifold conduits 1316 disposed through a longitudinally extending portion 1314 of the central manifold 1302. For clarity of description, a set of one wall conduit 1312, one lid conduit 1310, and one central manifold conduit 1316 are shown in the figure.

Two valves 1508a and 1508b (one valve is shown in the figure) are mounted to the central manifold 1302. Each valve is a three-port valve having two inlets and one outlet. Valve 1508a controls delivery of a silicon precursor and a purge gas to one or more outer gas channels 3010. Valve 1508a is coupled to the silicon precursor source through the wall conduit 1312a, through the lid conduit 1310, and through the central manifold conduit 1316 and is coupled to the purge gas source through the wall conduit 1312c, through the lid conduit 1310, and through the central manifold conduit 1316.

Valve 1508b controls delivery of a nitrogen precursor and a purge gas to a central gas channel 3008. Valve 1508b is coupled to the nitrogen precursor source through the wall conduit 1312b, through the lid conduit 1310, and through the central manifold conduit 1316 and is coupled to the purge gas source through the wall conduit 1312c, through the lid conduit 1310, and through the central manifold conduit 1316.

Each of the valve 1508a, 1508b provides a continuous flow of a purge gas in which pulses of a precursor (a silicon precursor or nitrogen precursor) are dosed into the stream of the continuous flow of the purge gas. The valves 1508a, 1508b are preferably electrically actuated valves but may be other types of valves, such as pneumatically actuated valves. Examples of electrically actuated valves and pneumatically actuated valves include those available from Fujiken of Osaka, Japan.

The faceplate 3006 includes two discrete paths therethrough. One discrete path is through a plurality of holes 3054 formed through the faceplate 3006 to accommodate a gas flow therethrough from the outer gas channels 3010 to the processing region 806. Another discrete path is through a gas inlet 3014 in communication with grooves 3048 having holes 3050 to accommodate a gas flow therethrough from the central gas channel 3008 to the processing region 806.

Therefore, the silicon precursor is provided through the outer gas channels 3010, through the holes 3054 of the faceplate 3006 to the processing region 806. The nitrogen precursor is provided through the central gas channel 3008, through the gas inlet 3014, through the grooves 3048, through the holes 3050 to the processing region 806.

The chamber 1106 may further include a gate valve 1304 atop the central manifold 1302 to control delivery of a plasma from a plasma cleaning unit (not shown) through the central gas channel 3008 and/or the outer gas channels 3010.

The chamber 1106 further includes a liner 1027 circumferentially disposed about the substrate support 1028. The liner 1027 includes a pumping channel 1025 which is coupled to a vacuum system to evacuate gases from the process region 806 and to maintain the processing region 806 at a desired pressure. The liner 1027 is also sized and shaped to define a gap 1308 between the liner 1027 and the chamber body 902. A liner purge gas may be provided from the bottom of the chamber 1106 into the gap 1308 to flows radially outward and then upward to the pumping channel 1025. The chamber 106 may further include a gap 1306 between the liner 1027 and the stem of the substrate support 1028 to provide a bottom purge gas between the substrate support 1028 and the liner 1027.

The chamber may further include faceplate purge ports 1320 formed at a gap between the lid 904 and the chamber body 902. The purge ports 1320 define a space for the flow of purge gas to travel to prevent deposition of undesirable gas flow near these chamber components.

### EXAMPLES

The following examples will now be described and set forth details and features concerning embodiments of depositing a silicon nitride film. The following examples should not be construed to limit the scope of the invention unless expressly set forth in the claims.

### Example 1

Silicon nitride films were deposited by cyclical layer deposition over Substrates 1-5 at different heater temperatures. Hexachlorodisilane was used as the silicon precursor, and ammonia was used as the nitrogen precursor. Cyclical layer deposition was performed at a cycle time of about 1 second and at a chamber pressure of about 7.5 Torr. The thicknesses of the deposited silicon nitride films were measured. The deposition rates were calculated and are shown in Table 1.

TABLE 1

| | Substrate Heater | Deposition Rate | Deposition Rate |
|---|---|---|---|
| Sample | Temperature (° C.) | (Å/cycle) | (Å/min) |
| Substrate 1 | 600 | 0.237 | 14.22 |
| Substrate 2 | 650 | 0.530 | 31.80 |
| Substrate 3 | 700 | 0.920 | 55.20 |
| Substrate 4 | 750 | 1.535 | 92.10 |
| Substrate 5 | 770 | 1.805 | 108.30 |

### Example 2

Silicon nitride films were deposited by cyclical layer deposition over Substrates 6-11. Each substrate comprised a bare silicon wafer. Hexachlorodisilane was used as the silicon precursor, and ammonia was used as the nitrogen precursor. Cyclical layer deposition was performed at a heater temperature of about 650° C. Thicknesses, refractive indexes, mechanical particle levels for particles greater than 0.16 in size were measured with a 3 mm-edge exclusion and are shown in Table 2.

TABLE 2

| | | | | Non- | | | |
|---|---|---|---|---|---|---|---|
| | Wafer | | | Uniformity | Refractive | RI | |
| | Size | Number | Thickness | 1-Sigma | Index | 1-Sigma | Particle |
| Sample | (mm) | of Cycles | Ave (Å) | (%) | Average | (%) | Adders |
| Substrate | 300 | 200 | 203.47 | 4.355- | 1.9936 | 0.319- | 150 |
| 6 | | | | 49 pts | | 9 pts | |
| Substrate | 200 | 450 | 470.15 | 3.395- | 1.9091 | 0.181- | |
| 7 | | | | 49 pts | | 49 pts | |
| Substrate | 200 | 500 | 616.15 | 2.117- | 1.9598 | 0.181- | |
| 8 | | | | 49 pts | | 49 pts | |
| Substrate | 200 | 470 | 442.56 | 3.695- | 1.9963 | 0.146- | |
| 9 | | | | 49 pts | | 49 pts | |
| Substrate | 200 | 470 | 521.98 | 2.871- | 2.0126 | 0.096- | |
| 10 | | | | 49 pts | | 49 pts | |
| Substrate | 300 | 200 | 136.38 | 1 pt | 2.0262 | 1 pt | 73 |
| 11 | | | | | | | |

### Example 3

Silicon nitride films were deposited by cyclical layer deposition over Substrates 12-14. Each substrate comprised a 300 mm diameter patterned wafer. Hexachlorodisilane was used as the silicon precursor, and ammonia was used as the nitrogen precursor. Hexachlorodisilane was delivered utilizing an injector heated to a temperature about 70° C. The parameters and resultant film properties are shown in Table 3.

TABLE 3

| | Substrate 12 | Substrate 13 | Substrate 14 |
|---|---|---|---|
| Heater Temp | 650 | 650 | 700 |
| (° C.) | | | |
| Wafer Temp | 600 | 600 | 650 |
| (° C.) | | | |
| Deposition Rate | 13 | 35 | 55 |
| (Å/min) | | | |
| Cycle Time (sec) | 5 | 1 | 1 |
| Å/cycle | 1 | 0.5 | 0.9 |
| Chamber Pressure | 6-9 | 7.5 | 7.5 |
| (Torr) | | | |
| Patterned Loading | <1% | <5% (A.R. of 1:1) | N/A |
| Effect | (A.R. of 4:1) | | |
| Step Coverage | >97% | >95% (A.R. of 1:1) | N/A |
| | (A.R. of 4:1) | | |
| H₂ (%) by | 6.5 | 10 | <10 |
| RBS/HFS | | | |
| CI (%) by RBS | 0.6 | 1 | <1 |
| N/Si by RBS | 1.3 | 1.3 | N/A |
| Refractive Index | 1.95 | 1.95 | N/A |
| Etch Rate vs. | 0.33 | N/A | N/A |
| Oxide in 1% HF | | | |
| Non-Uniformity | 2-4% | 2-4% | N/A |
| Stress (dyne/cm²) | 1−2e10 tensile | 1−2e10 tensile | 1−2e10 tensile |

### Example 4

Silicon nitride films were deposited by chemical vapor deposition over Substrates 15-17. Each substrate comprised a 200 mm diameter patterned wafer. Hexachlorodisilane was used as the silicon precursor, and ammonia was used as the nitrogen precursor. Hexachlorodisilane was delivered utilizing a bubbler heated to a temperature between about 30° C. and about 50° C. The parameters and resultant film properties are shown in Table 4.

TABLE 4

| | Substrate 15 | Substrate 16 | Substrate 17 |
|---|---|---|---|
| Heater Temp | 650 | 670 | 700 |
| (° C.) | | | |
| Wafer Temp | 600 | 620 | 650 |
| (° C.) | | | |
| Deposition Rate | 65 | 85 | 240 |
| (Å/min) | | | |
| Cycle Time (sec) | N/A | N/A | N/A |
| Å/cycle | N/A | N/A | N/A |
| Chamber Pressure | 10 | 10 | 10 |
| (Torr) | | | |
| Patterned Loading | 4%-9% | 3%-6.5% (A.R. 1.1) | 2%-5% |
| Effect | (A.R. 1:1) | | (A.R. 1.1) |
| Step Coverage | >95% | >95% (A.R. 1:1) | >95% |
| | (A.R. 1:1) | | (A.R. 1:1) |
| H₂ (%) by | 10 | N/A | 13 |
| RBS/HFS | | | |
| CI (%) by RBS | 0.9 | N/A | 0.7 |
| N/Si by RBS | 1.26 | N/A | 1.23 |
| Refractive Index | 1.93 | 1.95 | 1.98 |
| Etch Rate vs. | 1.0 | 1.0 | 0.9 |
| Oxide in 1% HF | | | |
| Non-Uniformity | N/A | N/A | N/A |
| Stress (dyne/cm²) | 1−2e10 tensile | 1−2e10 tensile | 1−2e10 tensile |

### Example 5

Silicon nitride films were deposited by chemical vapor deposition over Substrates 18-21. Each substrate comprised a 300 mm diameter patterned wafer. Silane (SiH₄) was used as the silicon precursor, and ammonia was used as the nitrogen precursor. The parameters and resultant film properties are shown in Table 5.

TABLE 5

| | Substrate 18 | Substrate 19 | Substrate 20 | Substrate 21 |
|---|---|---|---|---|
| Heater Temp | N/A | N/A | 750 | 800 |
| (° C.) | | | | |
| Wafer Temp | 600 | 650 | 700-720 | 770 |
| (° C.) | | | | |
| Deposition | 43 | 200 | 200-600 | 1,700 |
| Rate (Å/min) | | | | |
| Cycle Time | N/A | N/A | N/A | N/A |
| (sec) | | | | |
| Å/cycle | N/A | N/A | N/A | N/A |
| Chamber | 240 | 240 | 240 | 275 |
| Pressure | | | | |
| (Torr) | | | | |
| Patterned | >15% (A.R. | 15% (A.R. 4:1) | 12% (A.R. 1:1) | 20% (A.R. 1:1) |
| Loading Effect | 1:1) | | | |
| Step Coverage | N/A | N/A | 95% | 92% |
| H₂ (%) by | N/A | N/A | 9% | 8% |
| RBS/HFS | | | | |
| CI (%) by RBS | N/A | NA/ | N/A | N/A |
| N/Si by RBS | N/A | N/A | N/A | 1/28 |
| Refractive | N/A | N/A | 1.96 | 2 |
| Index | | | | |
| Etch Rate vs. | N/A | N/A | N/A | 1 |
| Oxide in 1% | | | | |
| HF | | | | |
| Non-Uniformity | N/A | >3% | <2% | <1.5% |
| Stress | 1−2e10 tensile | 1−2e10 tensile | 1−2e10 tensile | Stress |
| (dyne/cm²) | | | | (dyne/cm²) |

While the foregoing is directed to embodiments of the present invention, other and further embodiments of the invention may be devised without departing from the basic scope thereof, and the scope thereof is determined by the claims that follow.

1. A method of depositing a silicon nitride film over a substrate surface, comprising:
separately introducing one or more pulses of a nitrogen precursor and one or more pulses of a silicon precursor to a region adjacent to the substrate surface;
wherein a portion of the pulses of the nitrogen precursor and a portion of the pulses of the silicon precursor are present together at the region adjacent the substrate surface.

2. The method of claim 1, further comprising removing a partial amount of the pulses of the nitrogen precursor from the region adjacent the substrate surface prior to introduction of the pulses of the silicon precursor.

3. The method of claim 1, further comprising removing a partial amount of the pulses of the silicon precursor from the region adjacent substrate surface prior to introduction of the pulses of the nitrogen precursor.

4. The method of claim 1, further comprising removing a partial amount of the pulses of the nitrogen precursor from the region adjacent the substrate surface prior to introduction of the pulses of the silicon precursor and removing a partial amount of the pulse of the silicon precursor from from the region adjacent the substrate surface prior to introduction of the pulses of the nitrogen precursor.

5. The method of claim 1, wherein the portion of the pulses of the nitrogen precursor and the portion of the pulses of the silicon precursor are present together at the region adjacent to the substrate surface to deposit silicon nitride at least partially by a gas-phase mechanism.

6. The method of claim 2, wherein the portion of the pulses of the nitrogen precursor and the portion of the pulses of the silicon precursor are present together at the region adjacent the substrate surface to form silicon nitride at least partially by a gas-phase mechanism in a silicon-rich environment.

7. The method of claim 3, wherein the portion of the pulses of the nitrogen precursor and the portion of the pulses of the silicon precursor are present together at the region adjacent the substrate surface to form silicon nitride at least partially by a gas-phase mechanism in a nitrogen-rich environment.

8. The method of claim 4, wherein the portion of the pulses of the nitrogen precursor and the portion of the pulses of the silicon precursor are present together at the region adjacent the substrate surface to form thin layers of silicon nitride in alternating silicon-rich environments and nitrogen-rich environments.

9. The method of claim 1, wherein a second portion of the pulses of the nitrogen precursor and a second portion of the pulses of the silicon precursor alternatively contact the substrate surface.

10. The method of claim 1, wherein a second portion of the pulses of the nitrogen precursor contacts the substrate surface having amounts of silicon precursor adsorbed thereon and wherein a second portion of the pulses of the silicon precursor contacts the substrate surface having amounts of nitrogen precursor adsorbed thereon.

11. The method of claim 1, wherein a second portion of the pulses of the nitrogen precursor is present separately at the region adjacent the substrate surface from the pulses of the silicon precursor and anneals a formed silicon nitride film.

12. The method of claim 1, wherein a second portion of the pulses of the silicon precursor is present separately at the region adjacent the substrate surface from the pulses of the nitrogen precursor and anneals a formed silicon nitride film.

13. The method of claim 1, further comprising providing a continuous flow of a purge gas, wherein the pulses of the nitrogen precursor and the pulses of the silicon precursor are dosed into the continuous flow of the purge gas.

14. The method of claim 2, wherein removing a partial amount of the pulses of the nitrogen precursor comprises providing a purge gas for a time period after the pulses of the nitrogen precursor and before the pulses of the silicon precursor in a duration sufficient to partially purge the region adjacent the substrate surface of the nitrogen precursor.

15. The method of claim 2, further comprising providing a purge gas for a time period after the pulses of the silicon precursor and before the pulses of the nitrogen precursor in a duration sufficient to substantially purge the region adjacent the substrate surface of the silicon precursor.

16. The method of claim 3, wherein removing a partial amount of the pulses of the silicon precursor comprises providing a purge gas for a time period after the pulses of the silicon precursor and before the pulses of the nitrogen precursor in a duration sufficient to partially purge the region adjacent the substrate surface of the silicon precursor.

17. The method of claim 3, further comprising providing a purge gas for a time period after the pulses of the nitrogen precursor and before the pulses of the silicon precursor in a duration sufficient to substantially purge the region adjacent the substrate surface of the nitrogen precursor.

18. The method of claim 4, wherein removing a partial amount of the pulses of the nitrogen precursor comprises providing a purge gas for a time period after the pulses of the nitrogen precursor and before the pulses of the silicon precursor in a duration sufficient to partially purge the region adjacent the substrate surface of the nitrogen precursor and wherein removing a partial amount of the pulses of the silicon precursor comprises providing the purge gas for a time period after the pulses of the silicon precursor and before the pulses of the nitrogen precursor in a duration sufficient to partially purge the region adjacent the substrate surface of the silicon precursor.

19. A method of depositing a silicon nitride film over a substrate surface by providing a plurality of cycles of gases, each cycle comprising:
providing a continuous flow of a purge gas to the chamber;
dosing the continuous flow of the purge gas with at least one pulse of a nitrogen precursor, the pulse of the nitrogen precursor being provided for a time period between about 0.01 seconds and about 2.0 seconds; and
dosing the continuous flow of the purge gas with at least one pulse of a silicon precursor, the pulse of the silicon precursor being provided for a time period between about 0.01 seconds and about 2.0 seconds;
wherein a time period between the pulse of nitrogen precursor and the pulse of silicon precursor is between about 0.01 seconds and about 2.0 seconds.

20. The method of claim 19, wherein the time period between the pulse of the nitrogen precursor and the pulse of silicon precursor is about 0.2 seconds of less.

21. The method of claim 19, wherein for each cycle, for a first time period a section of the substrate surface is exposed simultaneously to the nitrogen precursor and the silicon precursor.

22. The method of claim 21, wherein for each cycle, for a second time period the section of the substrate surface is exposed to the nitrogen precursor.

23. The method of claim 21, wherein for each cycle, for a second time period the section of the substrate surface is exposed to the silicon precursor.

24. The method of claim 21, wherein for each cycle, for a second time period the section of the substrate surface is exposed to the nitrogen precursor and for a third time period the section of the substrate surface is exposed to the silicon precursor.

25. The method of claim 21, wherein during the first time period, silicon nitride is formed at least partially in a co-reaction mode.

26. A method of forming a silicon nitride film by cyclical layer deposition, comprising:
providing pulses of a silicon precursor and providing pulses of a nitrogen precursor to a substrate at a substrate temperature of about 600° C. or less.

27. The method of claim 26, wherein pulses of the silicon precursor and pulses of the nitrogen precursor are providing in a cycle time of 1.0 second or less.

28. The method of claim 27, wherein a time period between the pulses of the silicon precursor and the pulses of the nitrogen precursor is about 0.2 seconds or less.

29. The method of claim 27, wherein the deposition rate is between about 30 Å per minute and about 100 Å per minute.

30. The method of claim 26, wherein the silicon precursor comprises hexachlorodisilane.

31. The method of claim 30, wherein hexachlorodisilane comprises a low content of aluminum, copper, and germanium impurities.

32. The method of claim 26, wherein the nitrogen precursor comprises ammonia.

33. The method of claim 26, wherein a silicon nitride film providing a step coverage of about 95% or greater is deposited.

34. The method of claim 26, wherein a silicon nitride film providing a pattern loading effect of about 5% or less is deposited.

35. The method of claim 26, wherein a silicon nitride film having a purity level of about 95% or greater is deposited.
